(19) United States
(12) Patent Application Publication
(10) Pub. No.: US 2026/0110714 A1
(43) Pub. Date: Apr. 23, 2026

(54) VOLTAGE DETECTION CIRCUIT

(71) Applicant: DENSO CORPORATION, Kariya-city (JP)

(72) Inventors: Shogo KAWAHARA, Kariya-city (JP); Kazutaka HONDA, Kariya-city (JP)

(21) Appl. No.: 19/414,886

(22) Filed: Dec. 10, 2025

Related U.S. Application Data
(63) Continuation of application No. PCT/JP2024/025649, filed on Jul. 17, 2024.

(30) Foreign Application Priority Data
Aug. 2, 2023 (JP) 2023-126293

(51) Int. Cl. G01R 19/00; G01R 19/10; G01R 19/155

(52) U.S. Cl. CPC G01R 19/0038; G01R 19/10; G01R 19/155

(57) ABSTRACT

A voltage detection circuit includes: switches each of which includes a MOS transistor capable of opening and closing between a pair of input nodes and a pair of output nodes; a capacitance couple drive unit having a drive unit; and a selector that is connected between the pair of input nodes, selects one of voltages of the pair of input nodes, and outputs a selection signal having a potential corresponding to a selected voltage. The drive unit generates the drive signal using the potential of the selection signal as a reference potential. The selector includes two MOS transistors connected in series between the pair of input nodes. One of the two MOS transistors is a normal MOS transistor having a normal threshold voltage. An other of the two MOS transistors is a low-threshold MOS transistor having a threshold lower than the normal threshold.

### CROSS REFERENCE TO RELATED APPLICATION

The present application is a continuation application of International Patent Application No. PCT/JP2024/025649 filed on Jul. 17, 2024, which designated the U.S. and claims the benefit of priority from Japanese Patent Application No. 2023-126293 filed on Aug. 2, 2023. The entire disclosures of all of the above applications are incorporated herein by reference.

### TECHNICAL FIELD

The present disclosure relates to a voltage detection circuit with a fully differential configuration.

### BACKGROUND

A conceivable technique teaches a voltage detection circuit with a fully differential configuration that employs a switch circuit defined as a CCSW circuit. CCSW is an abbreviation for Capacitively-Coupled Switch. Hereinafter, the voltage detection circuit according to the conceivable technique will be referred to as the conventional art. The conceivable technique is configured with a selector that applies the higher voltage of the voltages at two input nodes as the substrate potential of a P-channel MOS transistor and the lower voltage of the voltages at the two input nodes as the substrate potential of an N-channel MOS transistor.

### SUMMARY

According to an example, a fully differential voltage detection circuit receives a voltage from each of a pair of input nodes, detects a differential voltage between received voltages, and outputs the differential voltage from a pair of output nodes. The fully differential voltage detection circuit may include: a plurality of switches each of which includes at least one MOS transistor provided so as to be capable of opening and closing between the pair of input nodes and the pair of output nodes; a capacitance couple drive unit that includes: a drive capacitor; and a drive unit that generates a drive signal for driving a gate of the at least one MOS transistor and supplies the drive signal to the gate of the at least one MOS transistor, and controls an on and off state of each of the plurality of switches by driving the gate of the at least one MOS transistor via the drive capacitor; and a selector that is connected between the pair of input nodes, selects one of voltages of the pair of input nodes, and outputs a selection signal having a potential corresponding to a selected voltage. The drive unit generates the drive signal using the potential of the selection signal output from the selector as a reference potential. The selector includes two MOS transistors connected in series between the pair of input nodes. One of the two MOS transistors is a normal MOS transistor having a normal threshold voltage. An other of the two MOS transistors is a low-threshold MOS transistor having a threshold lower than the normal threshold.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram schematically illustrating a configuration of a voltage detection circuit according to a first embodiment;

FIG. 2 is a diagram schematically illustrating the configuration of a battery monitoring IC according to a first embodiment;

FIG. 3 is a diagram showing a specific configuration example of a switch circuit according to the first embodiment;

FIG. 4 is a diagram illustrating the potential state of each part during a sample period when a positive voltage is input according to the first embodiment;

FIG. 5 is a diagram illustrating the potential state of each part during a hold period when a positive voltage is input according to the first embodiment;

FIG. 6 is a diagram illustrating the potential state of each part during a sample period when a negative voltage is input according to the first embodiment;

FIG. 7 is a diagram showing an example of an operation range, an indeterminate range, a voltage range, and a transmission range of each part according to the first embodiment;

FIG. 8 is a diagram schematically illustrating the configuration of a ΔΣ modulator according to the modification;

FIG. 9 is a diagram showing a specific configuration example of a switch circuit according to the second embodiment;

FIG. 10 is a diagram schematically illustrating a configuration of a voltage detection circuit according to a third embodiment; and

FIG. 11 is a diagram showing a specific configuration example of a switch circuit according to the third embodiment.

### DETAILED DESCRIPTION

The conceivable technique is intended to be used in a battery monitoring IC that monitors the voltage of a battery. IC is an abbreviation for integrated circuit. In the battery monitoring ICs, as the types of batteries which are detection targets increase, the voltage range that is a detectable voltage range tends to expand year by year. A change of the IC design for each type of battery leads to an increase in the variety of products, so it may be desirable for a battery monitoring IC to be able to detect a wide range of voltages, both positive and negative voltage range, with one chip, i.e., one AFE. “AFE” is an abbreviation for “Analog Front End”.

According to the conceivable technique, since it is possible to detect negative voltages, the voltage detection device is suitable for applications where the voltage of a fuel cell is a detection target. However, since the input range of positive voltages is relatively narrow, the voltage detection device is unsuitable for applications where the voltage of a lithium-ion battery having a range between 0 V to 5 V, for example, is a detection target. Furthermore, in the conceivable technique, when the input voltage is near 0 V, the selector may not operate, so that there is a possibility such that a leakage current is generated and a detection accuracy is reduced.

An object of the present embodiments is to provide a voltage detection circuit that can accurately detect a wide range of voltages while suppressing the occurrence of leakage current.

In one aspect of the present embodiments, a voltage detection circuit is a fully differential voltage detection circuit that inputs the voltages of a pair of input nodes, detects the difference between the voltages, and outputs the difference voltage from a pair of output nodes, and includes a plurality of switches, a capacitance couple drive unit, and a selector. Each of the plurality of switches includes at least one MOS transistor that is provided so as to be capable of opening and closing between the pair of input nodes and the pair of output nodes. The capacitance couple drive unit includes a drive capacitor and a drive unit that generates a drive signal for driving the gate of the MOS transistor and supplies the drive signal to the gate of the MOS transistor, and controls the on and off operations of each of the plurality of switches by driving the gate of the MOS transistor via the drive capacitor. The selector is connected between the pair of input nodes, selects one of the voltages at the pair of input nodes, and outputs a selection signal having a potential corresponding to the selected voltage.

The drive unit generates the drive signal using the potential of the selection signal output from the selector as a reference potential. The selector includes two MOS transistors connected in series between the pair of input nodes. One of the two MOS transistors is a normal MOS transistor having a normal threshold value, and the other of the two MOS transistors is a low-threshold MOS transistor having a threshold value lower than the normal threshold value. As will be described in detail later, this allows the operation range of the selector to be expanded.

According to the above configuration, when a positive voltage is input, the selector does not become indeterminate and no leak current occurs, so the potential state of each of the multiple switches can be made equivalent to that of a configuration without a selector. Therefore, with the above configuration, the input range and detection accuracy of the positive voltage can be made equivalent to those of a configuration without a selector. Furthermore, with the above configuration, similar to the conceivable technique, the negative voltage can be detected by the operation of the selector. In this way, with the above configuration, it is possible to detect negative voltages while maintaining the input range and detection accuracy of positive voltages at the same level as the configuration without a selector. Therefore, the above configuration provides the excellent effect of being able to accurately detect a wide range of voltages while suppressing the occurrence of leakage current.

Hereinafter, multiple embodiments will be described with reference to the drawings. In the embodiments, substantially the same components are denoted by the same reference numerals, and the description thereof will be omitted.

### First Embodiment

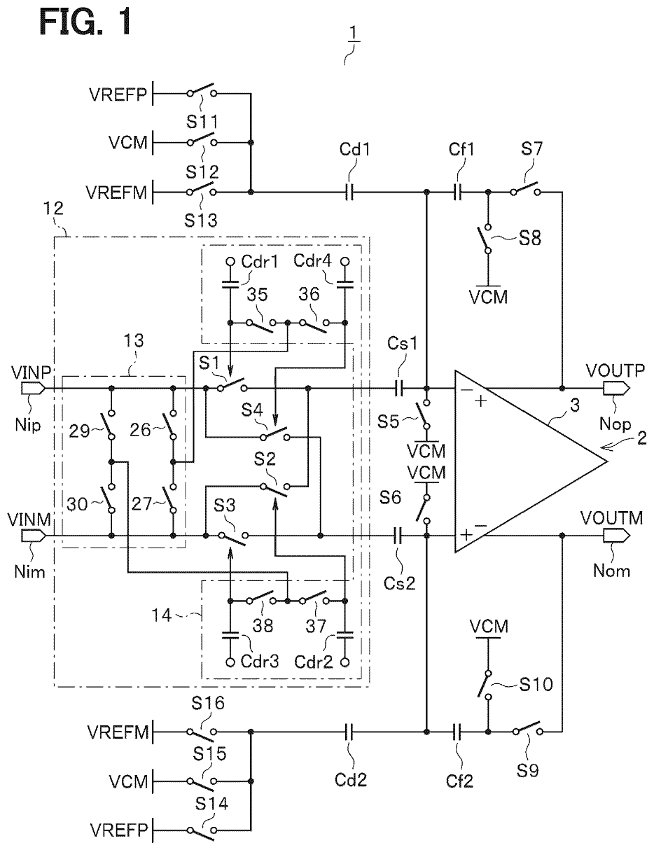

The following will describe a first embodiment with reference to FIG. 1 to FIG. 8.

### (Overall Configuration)

As shown in FIG. 1, the voltage detection circuit 1 of this embodiment includes a fully differential switched capacitor amplifier 2 having a pair of input nodes Nip and Nim and a pair of output nodes Nop and Nom, and various circuits not shown. It should be noted that, in this specification, the switched capacitor amplifier may be abbreviated as SC amplifier. The voltage detection circuit 1 receives the voltage VINP at the input node Nip and the voltage VINM at the input node Nim, detects the difference voltage between them, and outputs the difference voltage from the output nodes Nop and Nom. The voltage detection circuit 1 is configured as an IC to be mounted on a vehicle such as an automobile together with other circuit elements (not shown).

The SC amplifier 2 includes a differential output operational amplifier 3, capacitors Cs1, Cs2, Cf1, Cf2, Cd1, and Cd2, and switches S1 to S16. The on/off states of switches S1 to S16 are controlled by a control circuit that is not shown in the drawings. Each capacitor, including capacitors Cs1, Cs2, Cf1, Cf2, Cd1, and Cd2, has two terminals. In the embodiments, to distinguish between the two terminals provided by the capacitor, one of the two terminals is sometimes referred to as the first terminal and the other of the two terminals as the second terminal.

The first terminal of the capacitor Cs1 is connected to the inversion input terminal of the operational amplifier 3. The common potential VCM can be applied to the first terminal of the capacitor Cs1 via the switch S5. The second terminal of the capacitor Cs1 is connected to the input node Nin through the switch S1, and is connected to the input node Nim through the switch S2. The first terminal of the capacitor Cs2 is connected to the non-inversion input terminal of the operational amplifier 3. The common potential VCM can be applied to the first terminal of the capacitor Cs2 via the switch S6. The second terminal of the capacitor Cc2 is connected to the input node Nim through the switch S3, and is connected to the input node Nip through the switch S4.

In this manner, the capacitors Cs1 and Cs2, which form a pair in the differential configuration, have their first terminals connected to the input terminals of the operational amplifier 3, and they function as a pair of sampling capacitors. The capacitors Cs1 and Cs2 have the same capacitance value. The “same capacitance value” in the present embodiments does not only refer to a situation where the capacitance values are exactly same, but also refers to a situation where there is a slight difference in the capacitance values as long as an advantageous effect is attained.

The first terminal of the capacitor Cf1 is connected to the inversion input terminal of the operational amplifier 3. The second terminal of the capacitor Cf1 is connected to the non-inversion output terminal of the operational amplifier 3 via the switch S7. In other words, the capacitor Cf1 is connected between the inversion input terminal and the non-inversion output terminal of the operational amplifier 3 via the switch S7. The common potential VCM can be applied to the second terminal of capacitor Cf1 via the switch S8.

The first terminal of the capacitor Cf2 is connected to the non-inversion input terminal of the operational amplifier 3. The second terminal of the capacitor Cf2 is connected to the inversion output terminal of the operational amplifier 3 via the switch S9. In other words, the capacitor Cf2 is connected between the non-inversion input terminal and the inversion output terminal of the operational amplifier 3 via the switch S9. The common potential VCM can be applied to the second terminal of capacitor Cf2 via the switch S10. In this manner, the capacitors Cf1 and Cf2, which form a pair in the differential configuration, are connected between the input terminal and the output terminal of the operational amplifier 3, and they function as a pair of feedback capacitors. The capacitors Cf1 and Cf2 have the same capacitance value.

The first terminal of the capacitor Cd1 is connected to the inversion input terminal of the operational amplifier 3. A reference voltage VREFP can be applied to the second terminal of the capacitor Cd1 via the switch S11. A common potential VCM can be applied to the second terminal of the capacitor Cd1 via the switch S12. Furthermore, a reference voltage VREFM can be applied to the second terminal of the capacitor Cd1 via the switch S13. The reference voltages VREFP and VREFM are examples of DAC voltages output from the D/A converter, which is not shown. In the present embodiments, the digital-to-analog (i.e., D/A) converter may also be referred to as a DAC.

The first terminal of capacitor Cd2 is connected to the non-inversion input terminal of the operational amplifier 3. A reference voltage VREFP can be applied to the second terminal of the capacitor Cd2 via the switch S14. A common potential VCM can be applied to the second terminal of the capacitor Cd2 via the switch S15. Furthermore, a reference voltage VREFM can be applied to the second terminal of the capacitor Cd2 via the switch S16. In this manner, the capacitors Cd1 and Cd2, which form a pair in the differential configuration, are capable of storing charge in accordance with the DAC voltage and have their first terminals connected to the input terminals of the operational amplifier 3, functioning as a pair of DAC capacitors. The capacitors Cd1 and Cd2 have the same capacitance value.

Although not shown, the SC amplifier 2 includes a common-mode feedback circuit that controls the common-mode level of the output voltage of the operational amplifier 3. In the above configuration, the common mode feedback circuit operates to perform feedback control so that the common mode level of the output voltage of the operational amplifier 3 becomes the common potential VCM. In the SC amplifier 2, the common potential of each circuit is set to the common potential VCM.

The SC amplifier 2 samples the input voltages VINP and VINM, which are provided via a pair of input nodes Nip and Nim, using capacitors Cs1 and Cs2. The SC amplifier 2 amplifies the input voltages VINP and VINM by transferring the sampled charges via the capacitors Cf1 and Cf2, and outputs the amplified output voltages VOUTP and VOUTM from the output terminal of the operational amplifier 3. The non-inversion output terminal of the operational amplifier 3 is connected to an output node Nop. The inversion output terminal of the operational amplifier 3 is connected to an output node Nom. Therefore, the output voltages VOUTP and VOUTM are output to the subsequent circuit via a pair of the output nodes Nop and Nom.

### <Application Example of Voltage Detection Circuit>

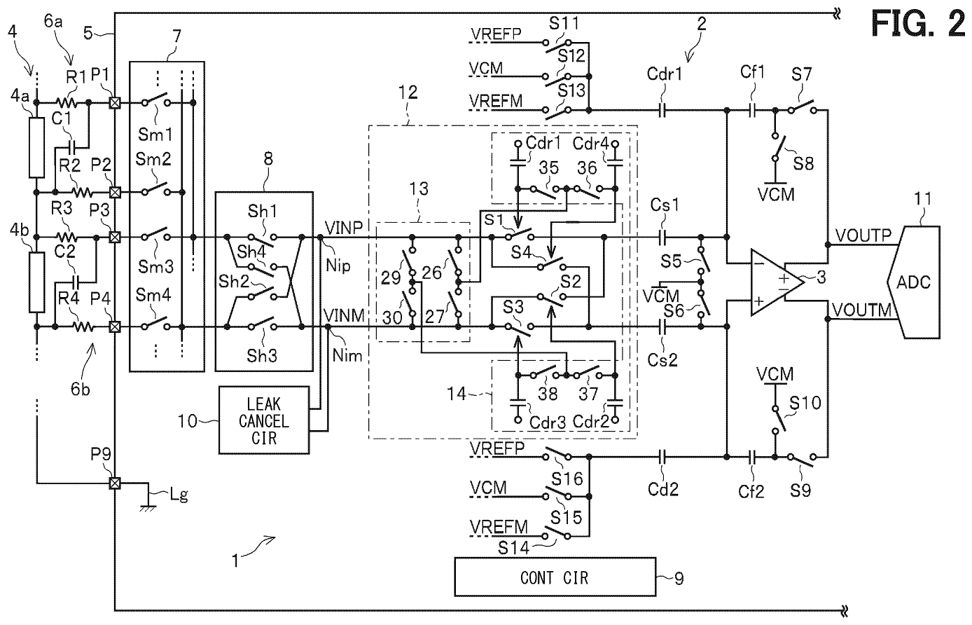

As shown in FIG. 2, the voltage detection circuit 1 of this embodiment can be applied to a battery monitoring IC 5 that monitors a battery pack 4 mounted on a vehicle. The battery pack 4 includes a lithium ion battery, a fuel cell, or the like, and a plurality of battery cells 4a, 4b and the like are connected in series in multiple stages. Therefore, a common mode voltage is superimposed on the multiple battery cells 4a, 4b, and so on. This common mode voltage becomes higher toward the battery cell connected to the upper voltage side of the battery pack 4, that is, to the high potential side of the battery pack 4, and its maximum value is a relatively high voltage of about several hundred volts, for example. Note that FIG. 2 only shows a portion, i.e., two battery cells 4a and 4b, and the corresponding configuration.

The negative terminal P9 of the battery cell (not shown) located at the bottom of the battery pack 4, that is, on the lowest potential side, is connected to the ground line Lg. The battery monitoring IC 5 has functions such as detecting and amplifying the voltage between each terminal of the battery cells 4a, 4b in the battery pack 4. The battery monitoring IC 5 is also equipped with a function to detect the current flowing through the battery cells 4a and 4b. The battery monitoring IC 5 has terminals P1 and P2 corresponding to the terminals of the battery cell 4a, terminals P3 and P4 corresponding to the terminals of the battery cell 4b, and a terminal P9 for supplying a ground potential of 0 V.

Each terminal of the battery cell 4a is connected to the terminals P1 and P2 via a filter 6a. The filter 6a is an RC filter and includes resistors R1, R2, and a capacitor C1. Each terminal of the battery cell 4b is connected to the terminals P3 and P4 via a filter 6b. The filter 6b is an RC filter configured similarly to filter 6a and includes resistors R3, R4, and a capacitor C2. A terminal P9 is configured as the negative terminal of the battery cell with the lowest potential and is connected to the ground line Lg.

The battery monitoring IC 5 includes a voltage detection circuit 1, a multiplexer 7 and a switch circuit 8. The voltage detection circuit 1 includes an SC amplifier 2, a control circuit 9, a leakage cancellation circuit 10, an A/D converter 11, and various digital circuits (not shown). In the embodiments, the A/D converter may be abbreviated as ADC. The control circuit 9 controls the overall operation of the battery monitoring IC 5, and includes as part of its configuration a capacitance couple drive unit that controls the on/off states of the switches S1 to S4 provided in the voltage detection circuit 1. The leakage cancellation circuit 10 is a differential circuit that cancels the charge leaking from the pair of input nodes Nip and Nim due to the operation of the voltage detection circuit 1.

The multiplexer 7 selects one of the voltages at the terminals P1 and P2, the voltages at the terminals P3 and P4, and the like by switching on and off the switches Sm1, Sm2, Sm3, Sm4, and the like, and outputs the one voltage to the subsequent stage. The differential analog signal selected by the multiplexer 7 is input to the voltage detection circuit 1 via a switch circuit 8 having a configuration including a chop switch in which four switches Sh1, Sh2, Sh3, and Sh4 are cross-connected. In the voltage detection circuit 1, the SC amplifier 2 receives the differential analog signal, integrates the differential analog signal, and outputs the integrated voltage to the ADC 11 at the subsequent stage. When the ADC 11 receives the integrated voltage, the ADC 11 quantizes the voltage into multiple levels and outputs it as a digital signal. The digital output is outputted digitally after executing the predetermined digital processing.

According to the above configuration, the pair of input nodes Nip, Nim of the voltage detection circuit 1 can be connected to the terminals of the battery cells 4 a, 4 b and the like that constitutes the battery pack 4. The voltage detection circuit 1 constitutes a part of a differential sample hold circuit that outputs a detection voltage corresponding to the input voltages VINP and VINM. The voltage detection circuit 1 also constitutes a part of a level shift circuit that reduces the relatively high common mode voltage superimposed on each of the battery cells 4a, 4b, and the like to a relatively low common mode voltage.

The output voltages VOUTP and VOUTM output from the SC amplifier 2 of the voltage detection circuit 1 correspond to detection voltages corresponding to the input voltages VINP and VINM, and are converted into digital data by the ADC 11 of a differential input type. This digital data represents the detection values of the input voltages VINP and VINM, and is acquired by a higher-stage control device (not shown). The voltage detection circuit 1 is configured to be able to add an offset so that the output voltages VOUTP and VOUTM fall within the input voltage range of the ADC 11, for example, a voltage range of +2.5V to −2.5V.

### <Specific Configuration of Switch Circuit>

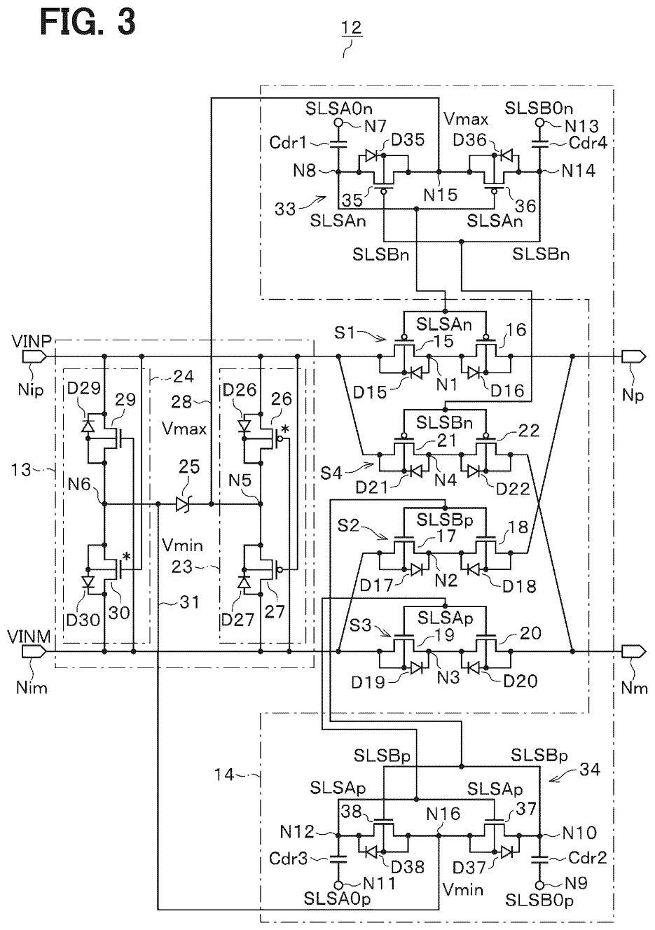

In the above configuration, a plurality of switches S1 to S4 connected between a pair of input nodes Nip, Nim and a pair of sampling capacitors Cs1, Cs2 having a sampling capacitance, together with a selector 13 and a capacitance couple drive unit 14, constitute a switch circuit 12, which is a CCSW circuit, as shown in FIGS. 1 and 2. In FIGS. 1 and 2, the configurations of the selector 13 and the capacitance couple drive unit 14 are shown in a simplified manner, but their detailed configurations will be described later with reference to FIG. 3. The switch circuit 12 including the switches S1 to S4 constitutes a part of the SC amplifier 2, and as a specific configuration thereof, for example, a configuration as shown in FIG. 3 can be adopted.

In the following embodiments, of the pair of input nodes Nip, Nim, the input node Nip on the high potential side may be referred to as the high potential side input node, and the input node Nim on the low potential side may be referred to as the low potential side input node. In the following embodiments, among the multiple switches S1 to S4, the switches S1 and S4 connected to the high potential side input node may be referred to as high potential side switches, and the switches S2 and S3 connected to the low potential side node may be referred to as low potential side switches.

As shown in FIG. 3, the switch circuit 12 includes a selector 13 and a capacitance couple drive unit 14 in addition to the switches S1 to S4. The switches S1 to S4 are provided so as to be able to open and close between the input nodes Nip, Nim and the output nodes Nop, Nom, and each switch S1 to S4 includes at least one MOS transistor. In this case, the high potential side switch is provided by two P-channel MOS transistors connected in series, and the low potential side switch is provided by two N-channel MOS transistors connected in series.

The specific configuration of the switches S1 to S4 is described as follows. The switch S1 is provided by two P-channel MOS transistors 15 and 16 connected in series. In the present embodiments, the P-channel MOSFET may also be referred to as a P-MOS transistor. The source of the P-MOS 15 is connected to the input node Nip, and the drain thereof is connected to the node N1. The drain of the P-MOS 16 is connected to the node N1, and the source thereof is connected to the node Np.

The node N1 is an example of an intermediate node which is an interconnection node between the two P-MOS transistors 15 and 16. The node Np is connected to the second terminal of the capacitor Cs1 and corresponds to the higher potential side output node of the pair of output nodes of the switch circuit 12. The back gate of the P-MOS 15 is connected to the source thereof. The back gate of the P-MOS 16 is connected to the source thereof. That is, the back gates of the P-MOSs 15 and 16 are connected to the terminal of their source or drain that is not connected to the node N1, which is the intermediate node.

In a MOS transistor, the back gate and the body are synonymous, so in the embodiments, the back gate of each MOS transistor including the PMOSs 15 and 16 may be referred to as the body. Between the body and drain of the P-MOS 15, there is a body diode D15 with the drain side serving as the anode. Between the body and drain of the P-MOS 16, there is a body diode D16 with the drain side serving as the anode. That is, in the switch S1, the body diodes D15 and D16 face each other. The gates of the P-MOSs 15 and 16 are connected to the capacitance couple drive unit 14, and are controlled by the capacitance couple drive unit 14 to be turned on and off.

The switch S2 is provided by two N-channel MOS transistors 17 and 18 connected in series. In the present embodiments, the N-channel MOS transistor may also be referred to as a N-MOS transistor. The source of the N-MOS 17 is connected to the input node Nim, and the drain thereof is connected to the node N2. The drain of the N-MOS 18 is connected to the node N2, and the source thereof is connected to the node Np.

The node N2 is an example of an intermediate node which is an interconnection node between the two N-MOS transistors 17 and 18. The back gate of the N-MOS 17 is connected to the source thereof. The back gate of the N-MOS 18 is connected to the source thereof. That is, the back gates of the N-MOSs 17 and 18 are connected to the terminal of their source or drain that is not connected to the node N2, which is the intermediate node.

Between the body and drain of the N-MOS 17, there is a body diode D17 with the body side serving as the anode. Between the body and drain of the N-MOS 18, there is a body diode D18 with the body side serving as the anode. That is, in the switch S2, the body diodes D17 and D18 face each other. The gates of the N-MOSs 17 and 18 are connected to the capacitance couple drive unit 14, and are controlled by the capacitance couple drive unit 14 to be turned on and off.

The switch S3 is provided by two N-MOS transistors 19 and 20 connected in series. The source of the N-MOS 19 is connected to the input node Nim, and the drain thereof is connected to the node N3. The drain of the N-MOS 20 is connected to the node N3, and the source thereof is connected to the node Nm. The node N3 is an example of an intermediate node which is an interconnection node between the two N-MOS transistors 19 and 20.

The node Nm is connected to the second terminal of the capacitor Cs2 and corresponds to the lower potential side output node of the pair of output nodes of the switch circuit 12. The back gate of the N-MOS 19 is connected to the source thereof. The back gate of the N-MOS 20 is connected to the source thereof. That is, the back gates of the N-MOSs 19 and 20 are connected to the terminal of their source or drain that is not connected to the node N3, which is the intermediate node.

Between the body and drain of the N-MOS 19, there is a body diode D19 with the body side serving as the anode. Between the body and drain of the N-MOS 20, there is a body diode D20 with the body side serving as the anode. That is, in the switch S3, the body diodes D19 and D20 face each other. The gates of the N-MOSs 19 and 20 are connected to the capacitance couple drive unit 14, and are controlled by the capacitance couple drive unit 14 to be turned on and off.

The switch S4 is provided by two P-MOS transistors 21 and 22 connected in series. The source of the P-MOS 21 is connected to the input node Nip, and the drain thereof is connected to the node N4. The drain of the N-MOS 22 is connected to the node N4, and the source thereof is connected to the node Nm. The node N4 is an example of an intermediate node which is an interconnection node between the two P-MOS transistors 21 and 22. The back gate of the P-MOS 21 is connected to the source thereof. The back gate of the P-MOS 22 is connected to the source thereof. That is, the back gates of the P-MOSs 21 and 22 are connected to the terminal of their source or drain that is not connected to the node N4, which is the intermediate node.

Between the body and drain of the P-MOS 21, there is a body diode D21 with the drain side serving as the anode. Between the body and drain of the P-MOS 22, there is a body diode D22 with the drain side serving as the anode. That is, in the switch S1, the body diodes D21 and D22 face each other. The gates of the P-MOSs 21 and 22 are connected to the capacitance couple drive unit 14, and are controlled by the capacitance couple drive unit 14 to be turned on and off.

The selector 13 is connected between a pair of input nodes Nip and Nim, selects one of the voltages VINP and VINM of the pair of input nodes Nip and Nim, and outputs a selection signal having a potential corresponding to the selected voltage. The selector 13 includes a maximum selector 23, a minimum selector 24, and a Zener diode 25. Each of the maximum selector 23 and the minimum selector 24 includes two MOS transistors connected in series between a pair of input nodes Nip and Nim. The two MOS transistors included in the maximum selector 23 are P-MOS transistors 26 and 27.

The drain of the P-MOS 26 is connected to the input node Nip, and the drain of the P-MOS 27 is connected to the input node Nim. The gate of the P-MOS 26 is connected to the input node Nim, and the gate of the P-MOS 27 is connected to the input node Nip. The sources and back gates of the P-MOSs 26 and 27 are both connected to the node N5. The node N5 is an output node for outputting the selection signal Vmax in the maximum selector 23, and is connected to a signal line 28. That is, the maximum selector 23 is configured to output the signal of the node N5, which is the interconnection node between the two PMOSs 26 and 27, as the selection signal Vmax.

Between the body and drain of the P-MOS 26, there is a body diode D26 with the drain side serving as the anode. Between the body and drain of the P-MOS 27, there is a body diode D27 with the drain side serving as the anode. That is, in the maximum selector 23, the body diodes D26 and D27 face each other. With this configuration, the maximum selector 23 selects the higher one of the voltages VINP and VINM, and outputs a selection signal Vmax having a potential corresponding to the selected voltage to other circuits via the node N5 and the signal line 28.

The P-MOS 27, which is one of the two P-MOSs 26 and 27 included in the maximum selector 23, is a normal MOS transistor having a normal threshold value. The other of the two PMOSs 26 and 27 included in the maximum selector 23 is the P-MOS 26, which is a low-threshold MOS transistor having a threshold lower than the normal threshold. The low threshold MOS transistor also includes a depletion MOS transistor whose threshold is 0 V. In this embodiment, a depletion MOS transistor is used as the P-MOS 26. In FIG. 2 and other drawings, the symbols of MOS transistors that use depletion MOS transistors are distinguished by adding an asterisk (*) near the gate.

The two MOS transistors included in the minimum selector 24 are N-MOS transistors 29 and 30. The drain of the N-MOS 29 is connected to the input node Nip, and the drain of the N-MOS 30 is connected to the input node Nim. The gate of the N-MOS 29 is connected to the input node Nim, and the gate of the N-MOS 30 is connected to the input node Nip. The sources and back gates of the NMOS transistors 29 and 30 are both connected to the node N6. The node N6 is an output node for outputting the selection signal Vmin in the minimum selector 24 and is connected to the signal line 31. That is, the minimum selector 24 is configured to output the signal of the node N6, which is the interconnection node between the two N-MOS transistors 29 and 30, as the selection signal Vmin.

Between the body and drain of the N-MOS 29, there is a body diode D29 with the body side serving as the anode. Between the body and drain of the N-MOS 30, there is a body diode D30 with the body side serving as the anode. That is, in the minimum selector 24, the body diodes D29 and D30 face each other. With this configuration, the minimum selector 24 selects the lower one of the voltages VINP and VINM, and outputs a selection signal Vmin having a potential corresponding to the selected voltage to other circuits via the node N6 and the signal line 31.

The N-MOS 29, which is one of the two N-MOSs 29 and 30 included in the minimum selector 24, is a normal MOS transistor having a normal threshold value. The other N-MOS 30 of the two N-MOSs 29 and 30 included in the minimum selector 24 is a low-threshold MOS transistor having a threshold lower than the normal threshold. In this embodiment, a depletion MOS transistor is used as the N-MOS 30.

In the selector 13 configured as described above, there exists an operation indeterminate region where the selector 13 is unable to operate normally depending on the difference between the voltages VINP and VINM of the input nodes Nip and Nim. Therefore, in the above configuration, a Zener diode 25 is connected between the node N5 and the node N6, with the node N6 side serving as the anode. As a result, in the above-mentioned indeterminate operation region, the selection signals Vmax and Vmin are fixed to a predetermined potential relationship.

The capacitance couple drive unit 14 controls the operations of the switches S1 to S4 based on binary control signals SLSA0n, SLSB0n, SLSA0p, and SLSB0p given from the outside. The control signals SLSA0n to SLSB0p have a high level of +5V and a low level of 0V. The capacitance couple drive unit 14 controls the on/off states of the switches S1 to S4 by driving the gates of the MOS transistors 15 to 22 via the drive capacitors Cdr1 to Crd4.

The capacitance couple drive unit 14 is configured as a part of the control circuit 9 described above, and its specific configuration is described as follows. That is, the capacitance couple drive unit 14 includes a plurality of drive capacitors Cdr1, Cdr2, Cdr3, and Cdr4 provided corresponding to the switches S1 to S4, respectively, a P-MOS drive unit 33, and an N-MOS drive unit 34. In the following description, the P-MOS drive unit 33 and the N-MOS drive unit 34 may be simply referred to as the drive units 33 and 34. The drive capacitor Cdr1 is connected between a node N7 and a node N8 to which a control signal SLSA0n is applied. The node N8 is connected to the gates of the P-MOS transistors 15 and 16 of the switch S1. The drive capacitor Cdr2 is connected between a node N9 and a node N10 to which a control signal SLSB0p is applied. The node N10 is connected to the gates of the N-MOS transistors 17 and 18 of the switch S2.

The drive capacitor Cdr3 is connected between a node N11 and a node N12 to which a control signal SLSA0p is applied. The node N12 is connected to the gates of the N-MOS transistors 19 and 20 of the switch S3. The drive capacitor Crd4 is connected between a node N13 and a node N14 to which a control signal SLSB0n is applied. The node N14 is connected to the gates of the P-MOS transistors 21 and 22 of the switch S4. In this embodiment, the drive capacitors Cdr1 to Cdr4 are configured as comb type capacitors.

The drive units 33 and 34 supply drive signals SLSAn, SLSBn, SLSAp, and SLSBp to the gates of the MOS transistors 15 to 22 that constitute the switches S1 to S4, respectively. The drive signals SLSAn to SLSBp are binary signals that are either at an off level that turns off the MOS transistors 15 to 22 or at an on level that turns on the MOS transistors 15 to 22. Specifically, the on level and the off level are described as follows.

That is, when the driving target is an N-MOS, the on level is a level that satisfies the following expression (1), when the driving target is a P-MOS, the on level is a level that satisfies the following expression (2), and the off level is a level that satisfies the following expression (3). Here, the gate-source voltage of the MOS transistor is represented as VGS, and the threshold voltage of the MOS transistor is represented as Vt.

$$VGS > Vt \qquad ( 1 )$$

$$VGS < - Vt \qquad ( 2 )$$

$$VGS \approx 0 \qquad ( 3 )$$

The P-MOS drive unit 33 includes two P-MOSs 35 and 36. The drain of the P-MOS 35 is connected to the node N8, and the source thereof is connected to the node N15. The node N15 is connected to a signal line 28. The back gate of the P-MOS 35 is connected to the source thereof. The gate of the P-MOS 35 is connected to the node N14. Between the body and drain of the P-MOS 35, there is a body diode D35 with the drain side serving as the anode.

The drain of the P-MOS 36 is connected to the node N14, and the source thereof is connected to the node N15. The back gate of the P-MOS 36 is connected to the source thereof. The gate of the P-MOS 36 is connected to the node N8. Between the body and drain of the P-MOS 36, there is a body diode D36 with the drain side serving as the anode.

The P-MOS driver 33 configured as described above generates a drive signal SLSAn for driving the gates of P-MOSs 15 and 16 and a drive signal SLSBn for driving the gates of P-MOSs 21 and 22, using the potential of the selection signal Vmax output from the selector 13 as a reference potential. The drive signal SLSAn has the same logic as the control signal SLSA0n, and is supplied from the node N8 to the gates of the P-MOS transistors 15 and 16 of the switch S1. The drive signal SLSBn has the same logic as the control signal SLSB0n, and is supplied from the node N14 to the gates of the P-MOSs 21 and 22 of the switch S4.

The N-MOS drive unit 34 includes two N-MOSs 37 and 38. The drain of the N-MOS 37 is connected to the node N10, and the source thereof is connected to the node N16. The node N16 is connected to a signal line 31. The back gate of the N-MOS 37 is connected to the source thereof. The gate of the N-MOS 37 is connected to the node N12. Between the body and drain of the N-MOS 37, there is a body diode D37 with the body side serving as the anode.

The drain of the N-MOS 38 is connected to the node N12, and the source thereof is connected to the node N16. The back gate of the N-MOS 38 is connected to the source thereof. The gate of the N-MOS 38 is connected to the node N10. Between the body and drain of the N-MOS 38, there is a body diode D38 with the body side serving as the anode.

The N-MOS drive unit 34 configured as described above generates a drive signal SLSBp for driving the gates of N-MOSs 17 and 18 and a drive signal SLSAp for driving the gates of N-MOSs 19 and 20, using the potential of the selection signal Vmin output from the selector 13 as a reference potential. The drive signal SLSBp has the same logic as the control signal SLSB0p, and is supplied from the node N10 to the gates of the N-MOS transistors 17 and 18 of the switch S2. The drive signal SLSAp has the same logic as the control signal SLSA0p and is supplied from the node N12 to the gates of the N-MOS transistors 19 and 20 of the switch S3.

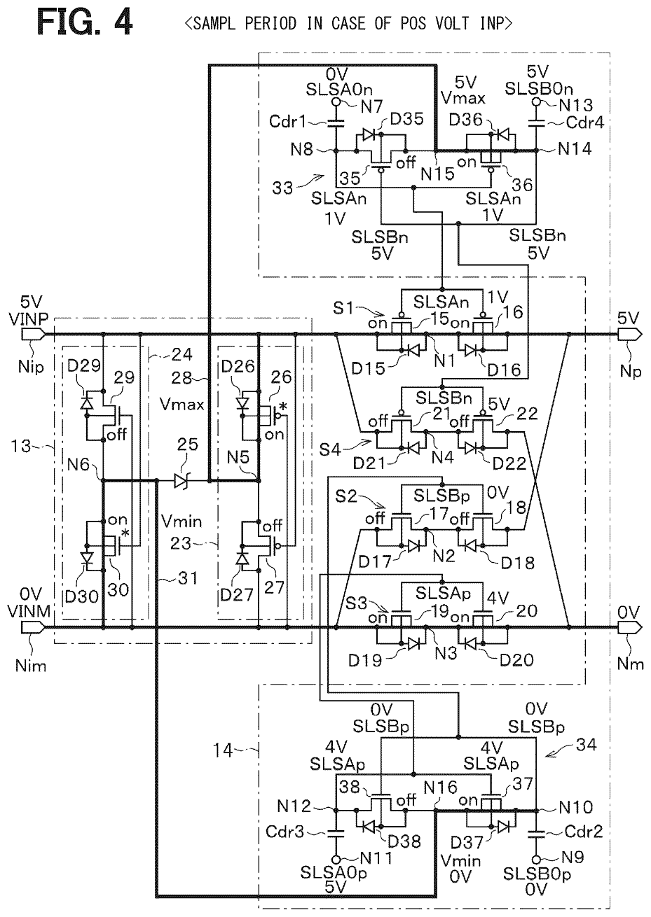

Next, the operation of the above configuration will be described with reference to FIG. 4 to FIG. 7.

The capacitance couple drive unit 14 controls the switches S1 and S3 and the switches S2 and S4 to turn on and off complementarily. In the embodiments, “complementarily turning on and off” does not exclude the case where a period during which both switches are turned off, that is, a so-called dead time, is provided. Hereinafter, the period during which switches S1 and S3 are turned on and switches S2 and S4 are turned off may be referred to as a sample period, and the period during which switches S1 and S3 are turned off and switches S2 and S4 are turned on may be referred to as a hold period.

In the SC amplifier 2 configured as described above, during the sample period, the capacitors Cs1 and Cs2 are charged by the voltages VINP and VINM of the input nodes Nip and Nim, respectively. In other words, the voltages VINP and VINM of the input nodes Nip and Nim are sampled by the capacitors Cs1 and Cs2. Furthermore, in the SC amplifier 2 configured as described above, during the hold period, the charges stored in the capacitors Cs1 and Cs2 are transferred to the subsequent circuit.

In the following, assuming such operation, the potential state of each part will be described when a positive voltage is input via the input nodes Nip and Nim, and when a negative voltage is input via the input nodes Nip and Nim. Here, it is assumed that when a positive voltage is input, the voltage VINP is +5V and the voltage VINM is 0V, and when a negative voltage is input, the voltage VINP is-2V and the voltage VINM is 0V. In FIGS. 4 to 6, the on/off states of each MOS transistor are distinguished by the presence or absence of hatching. Specifically, in FIGS. 4 to 6, only the MOS transistors that are turned on are hatched.

(1) Potential State of Each Part when Positive Voltage is Input

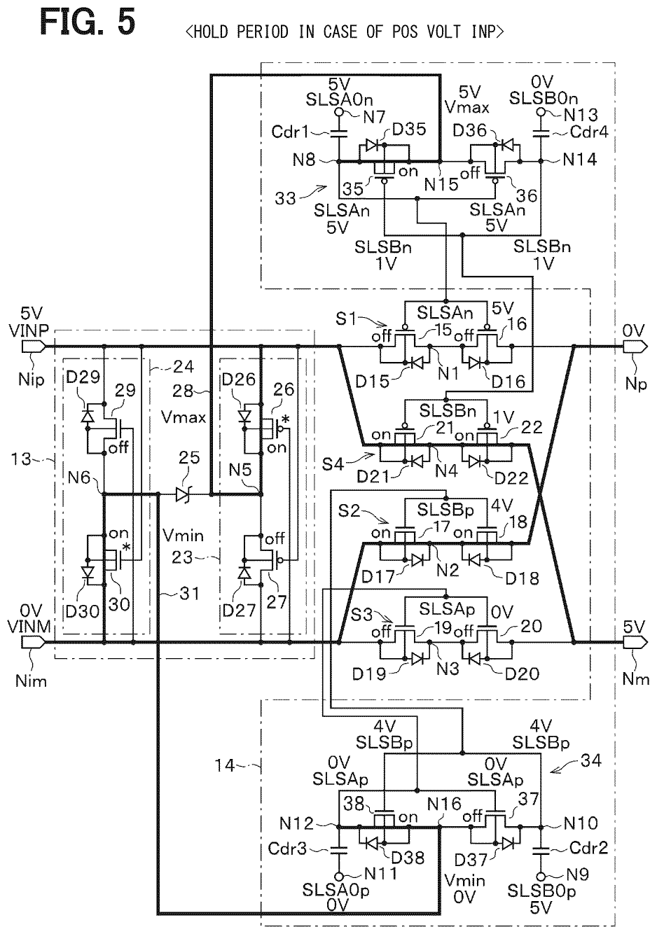

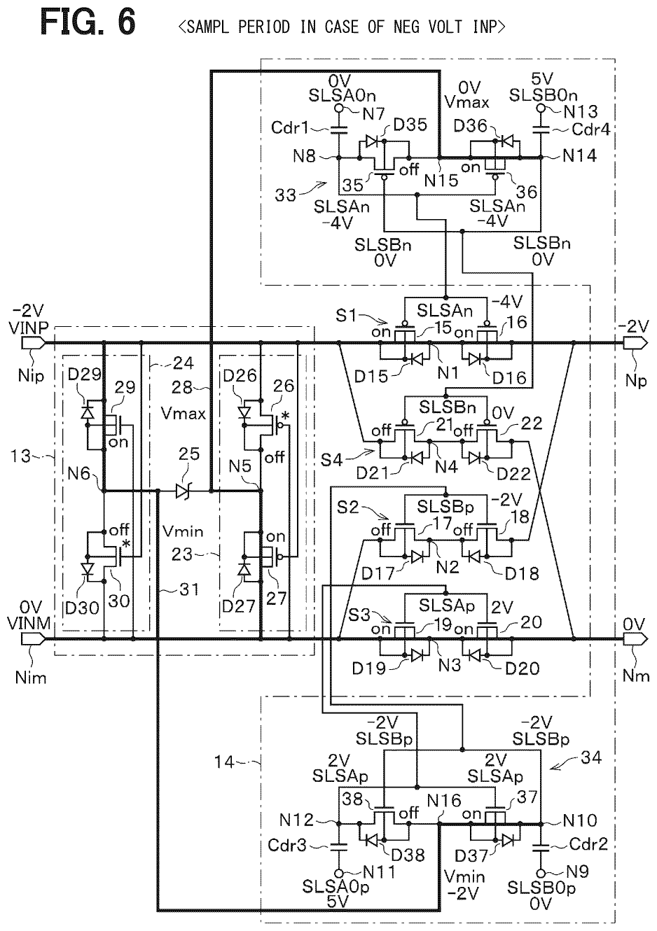

As shown in FIGS. 4 and 5, when a positive voltage is input, in the selector 13, the P-MOS 26 and the N-MOS 30 are turned on, and the P-MOS 27 and the N-MOS 29 are turned off. As a result, when a positive voltage is input, the potential of the selection signal Vmax becomes 5V and the potential of the selection signal Vmin becomes 0V. As shown in FIGS. 4 and 6, during the sample period, the control signals SLSA0n and SLSB0p are set to 0V, and the control signals SLSB0n and SLSA0p are set to 5V.

Therefore, as shown in FIG. 4, in the sample period when a positive voltage is input, in the drive units 33 and 34, the P-MOS 36 and N-MOS 37 are turned on, and the P-MOS 35 and N-MOS 38 are turned off. As a result, during the sample period when a positive voltage is input, the drive signal SLSAn becomes 1V, the drive signal SLSBn becomes 5V, the drive signal SLSAp becomes 4V, and the drive signal SLSBp becomes 0V. Therefore, during the sample period when a positive voltage is input, the P-MOSs 15 and 16 of the switch S1 and the N-MOSs 19 and 20 of the switch S3 are turned on, and the N-MOSs 17 and 18 of the switch S2 and the P-MOSs 21 and 22 of the switch S4 are turned off.

As shown in FIG. 5, during the hold period, the control signals SLSA0n and SLSB0p become 5V, and the control signals SLSB0n and SLSA0p become 0V. Therefore, as shown in FIG. 5, in the hold period when a positive voltage is input, in the drive units 33 and 34, the P-MOS 35 and N-MOS 38 are turned on, and the P-MOS 36 and N-MOS 37 are turned off. As a result, during the hold period when a positive voltage is input, the drive signal SLSAn becomes 5V, the drive signal SLSBn becomes 1V, the drive signal SLSAp becomes 0V, and the drive signal SLSBp becomes 4V. Therefore, during the hold period when a positive voltage is input, the P-MOSs 15 and 16 of the switch S1 and the N-MOSs 19 and 20 of the switch S3 are turned off, and the N-MOSs 17 and 18 of the switch S2 and the P-MOSs 21 and 22 of the switch S4 are turned on.

As described above, according to the configuration of this embodiment, when a positive voltage is input, the potential states of the switches S1 to S4 can be set to the same potential states as in a configuration in which the selector 13 is not provided. Furthermore, according to the configuration of this embodiment, the depletion MOS transistors are used as the P-MOS 26 and N-MOS 30 in the selector 13, which should be turned on when a positive voltage is input. Therefore, even if the input voltage VINP is near 0 V, the P-MOS 26 and N-MOS 30 can be reliably turned on. As a result, the potential of the MOS transistor that constitutes the switch that is turned off does not become indeterminate, and high accuracy of the output can be achieved. The case where the input voltage VINP is near 0V refers to the case where the input voltage VINP is equal to or lower than the threshold voltage Vt of the MOS transistor, for example, 0.7V or lower.

(2) Potential State of Each Part when Negative Voltage is Input

As shown in FIG. 6, when a negative voltage is input, in the selector 13, the P-MOS 27 and N-MOS 29 are turned on, and the P-MOS 26 and N-MOS 30 are turned off. As a result, when a negative voltage is input, the potential of the selection signal Vmax becomes 0V and the potential of the selection signal Vmin becomes-2V. Therefore, during the sample period when a negative voltage is input, in the drive units 33 and 34, the P-MOS 36 and N-MOS 37 are turned on, and the P-MOS 35 and N-MOS 38 are turned off.

As a result, during the sample period when a negative voltage is input, the drive signal SLSAn becomes-4V, the drive signal SLSBn becomes 0V, the drive signal SLSAp becomes 2V, and the drive signal SLSBp becomes-2V. Therefore, during the sample period when a negative voltage is input, the P-MOSs 15 and 16 of the switch S1 and the N-MOSs 19 and 20 of the switch S3 are turned on, while the N-MOSs 17 and 18 of the switch S2 and the P-MOSs 21 and 22 of the switch S4 are turned off. The potential state during the hold period when a negative voltage is input is the subject of differentiation with respect to the sample period when a negative voltage is input, so a description thereof will be omitted.

As described above, according to the configuration of this embodiment, when a negative voltage is input, the voltage VINP, which is the lower potential of the voltages VINP and VINM, is applied to the gate of the N-MOS that constitutes the switch that should be turned off among the switches S1 to S4, and the voltage VINM, which is the higher potential of the voltages VINP and VINM, is applied to the gate of the P-MOS that constitutes the switch that should be turned off, thereby reliably turning off those switches.

Furthermore, according to the configuration of this embodiment, when a negative voltage is input, a drive signal whose potential is changed to be higher than the voltage VINP by a level corresponding to the amplitude of the control signal is applied to the gate of an N-MOS constituting one of the switches S1 to S4 that should be turned on, and a drive signal whose potential is changed to be lower than the voltage VINM by a level corresponding to the amplitude of the control signal is applied to the gate of a P-MOS constituting one of the switches that should be turned on, thereby reliably turning on those switches.

The above-described embodiment provides the following effect.

According to the configuration of this embodiment, when a positive voltage is input, the selector 13 does not become indeterminate and no leakage current occurs, so the potential state of each of the multiple switches S1 to S4 can be made equivalent to a configuration in which the selector 13 is not provided. Therefore, according to the configuration of this embodiment, the input range and detection accuracy of the positive voltage can be made equivalent to those of a configuration in which the selector 13 is not provided.

Furthermore, according to the configuration of this embodiment, a negative voltage can be detected by the operation of the selector 13, as in the conceivable technique. As described above, the configuration of this embodiment makes it possible to detect the negative voltage while maintaining the input range and detection accuracy of the positive voltage at the same level as in a configuration without the selector 13. Therefore, according to the present embodiment, it is possible to provide the excellent effect of being able to accurately detect a wide range of voltages while suppressing the occurrence of leakage current.

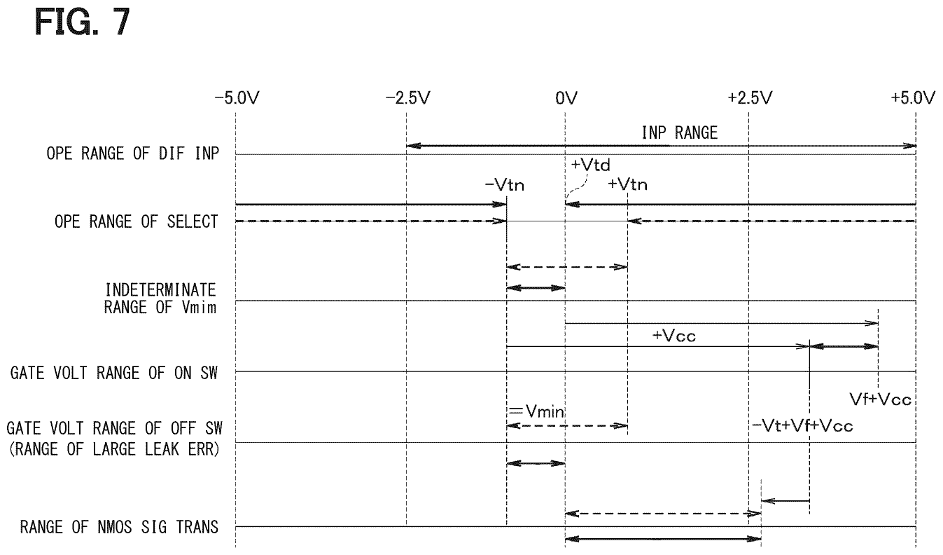

The effect obtained by this embodiment will be further clarified by comparing with the comparison example corresponding to the configuration of the conceivable technique. Therefore, the effects obtained by this embodiment will be described in detail below with reference to FIG. 7, while comparing this embodiment with a comparative example corresponding to the conceivable technique. In FIG. 7, the arrows indicating the ranges corresponding to the comparative example are indicated by dotted lines, and the arrows indicating the ranges corresponding to this embodiment are indicated by solid lines. In FIG. 7, Vf is the forward voltage of the diode, and Vcc is the drive voltage in the drive units 33 and 34.

In addition, in FIG. 7, assuming a sample period when a negative voltage is input, the gate voltage range of the N-MOS transistors 19 and 20 of the switch S3 that are turned on at that time, i.e., the voltage range of the drive signal SLSAp, is represented as the on SW gate voltage range, and the gate voltage range of the N-MOS transistors 17 and 18 of the switch S2 that are turned off at that time, i.e., the voltage range of the drive signal SLSBp, is represented as the off SW gate voltage range. In this case, the negative voltage input is assumed to be when the voltage VINP is in the range of “−Vt to 0V” and the voltage VINM is 0V.

As shown in FIG. 7, the positive operation range of the voltage detection circuit 1 of this embodiment is the same as that of the comparative example, and the differential voltage between the input nodes Nip and Nim is in the range of about +5.0 V. In the embodiments, the differential voltage between the input nodes Nip and Nim may be simply referred to as the differential voltage. The negative operation range of the voltage detection circuit 1 is the same as that of the comparative example, and the differential voltage is in the range of about −2.5 V. That is, the differential input operation range of the voltage detection circuit 1 of this embodiment is −2.5 V to +5.0 V.

Here, in this embodiment, the depletion MOS transistors are used for the P-MOS 26, which is one of the two P-MOS transistors 26 and 27 that constitute the maximum selector 23, and the N-MOS 30, which is one of the two N-MOS transistors 29 and 30 that constitute the minimum selector 24, so the operation range of the selector 13 is wider than in the comparative example. That is, in the comparative example, the positive side operation range of the selector is a range of +Vtn or more, which is, for example, about 0.7 V. Here, Vtn is usually the threshold value of a MOS transistor.

Therefore, in the comparative example, the Vmin indeterminate range in which the selection signal Vmin output from the minimum selector is indeterminate is the range from −Vtn to +Vtn, that is, the range from −0.7 V to +0.7 V. As a result, in the comparative example, in the range from −0.7 V to +0.7 V, the gate voltage of the N-MOS of the switch that is turned off becomes higher than the input voltage, so that the leakage occurs and the accuracy is reduced. In contrast to this, in this embodiment, the positive side operation range of the selector 13 is a range equal to or greater than +Vtd, which is, for example, 0 V. Here, Vtd is the threshold voltage of the depletion MOS transistor.

Therefore, in this embodiment, the Vmin indeterminate range is the range from −Vtn to +Vtd, that is, the range from −0.7 V to 0 V. As a result, in this embodiment, in the range from −0.7 V to 0 V, the gate voltage of the N-MOS of the switch that is turned off becomes higher than the input voltage, so that a leakage may occur, but it is possible to prevent the leakage from occurring in the range of 0 V or higher, that is, when a positive voltage is input.

As described above, according to this embodiment, the selector 13 always operates when the differential voltage is approximately 0 V or more, and the decrease in accuracy due to the leakage of the MOS transistors that constitutes the selector 13 can be reduced compared to the comparative example. In both the comparative example and this embodiment, the signal transmission range of the N-MOS is approximately from 0 V to +3.0 V. In the comparative example, since an N-MOS is present in the path through which the voltage VINP passes, although the voltage VINP is expected to be approximately +5.0 V at maximum, only a voltage up to approximately +3.0 V can be passed, so that the input range of the positive voltages becomes narrow.

In contrast to this, in this embodiment, since only the P-MOS exists in the path through which the voltage VINP passes, the input range of the positive voltage can be expanded compared to the comparative example. Furthermore, in this embodiment, the N-MOS is only present in the path through which the voltage VINM passes, and it is sufficient for it to pass 0 V, so there is no risk of the input range being narrowed due to the signal transmission range of the N-MOS. Although detailed description will be omitted, according to this embodiment, the input range on the P-MOS side is also expanded compared to the comparative example by the opposite operation to that on the N-MOS side.

Each of the switches S1 to S4 has a configuration in which two MOS transistors are connected in series, and the back gates of these MOS transistors are connected to the source or drain terminal of the MOS transistor that is not connected to the intermediate node, which is the interconnection node of the two MOS transistors. In this way, the body diodes of the two MOS transistors in the switches S1 to S4 face each other.

Therefore, with this configuration, no current flows through the body diode, and no error occurs. In particular, when the negative voltage is large, backflow does not occur through the body diode, and therefore the occurrence of errors associated with this backflow can be suppressed. Furthermore, with the above configuration, the body potential of each MOS transistor constituting the signal transmission switches S1 to S4 for transmitting the voltages VINP and VINM as the input signal to the subsequent stage can be fixed to the voltages VINP and VINM as the input signal, so that the advantage of increasing EMC tolerance is obtained.

In this embodiment, the capacitance couple drive unit 14 controls the on/off of each of the switches S1 to S4 by driving the gates of the MOS transistors 15 to 22 via the drive capacitors Cdr1 to Cdr4, which are comb-tooth capacitors. That is, in this embodiment, the switches S1 to S4 are configured to be driven by capacitance coupling. In addition, in this embodiment, the drive capacitors Cdr1 to Cdr4 are configured as comb-tooth capacitors.

With such a configuration, the following effects can be obtained. That is, with the above configuration, compared to when the drive capacitors Cdr1 to Cdr4 are configured using parallel plate capacitors, the circuit can be made smaller and the parasitic capacitance with other circuits inside the chip can be reduced, thereby reducing interference. Furthermore, in the capacitance couple drive configuration, noise is emitted in the sample and hold period, but by configuring the drive capacitors Cdr1 to Cdr4 as comb-tooth capacitors, the drive speed can be increased.

Normally, in a configuration driven by a capacitance couple, it is necessary to secure space between other circuits inside the chip or to place a guard ring to avoid noise interference, so that the chip area inevitably becomes large. In contrast, with the above configuration, when high-speed driving is not required, other circuits can be placed adjacent, thereby achieving the desired driving speed while reducing the overall chip area.

The voltage detection circuit 1 including the SC amplifier 2 of this embodiment constitutes a part of the battery monitoring IC 5, and more specifically, can be used as a level shift circuit in the battery monitoring IC 5. With this configuration, it is possible to transmit only the differential voltage through the capacitors Cs1 and Cs2, which are sampling capacitors, and therefore it is possible to shift the level of the common mode potential. Furthermore, with the above configuration, it is possible to detect signals in a wider range than the power supply voltage or the ground potential, both positive and negative.

Furthermore, if the voltage detection circuit 1 is applied to a battery monitoring IC 5, it is possible to detect the voltages of multiple battery cells with a single IC, and further, it is also possible to detect the voltage of a fuel cell in which the voltage of the battery cell becomes a negative voltage. Furthermore, according to the configuration of this embodiment, as described above, the input range and detection accuracy of the positive voltage can be made to be the same as in a configuration that does not have a selector 13, so the same battery monitoring IC 5 can be used both as a normal battery monitoring IC that monitors lithium ion batteries as the monitoring target and as a battery monitoring IC for FCs that monitors fuel cells as the monitoring target.

### <Modifications Regarding the Selector>

The configuration of this embodiment can be modified so that low-threshold MOS transistors other than depletion MOS transistors are used as the P-MOS 26 included in the maximum selector 23 and the N-MOS 30 included in the minimum selector 24. According to such a modified example, the selector 13 always operates when the differential voltage is equal to or greater than a voltage corresponding to a threshold lower than the normal threshold, and the accuracy degradation due to leakage of the MOS transistors constituting the selector 13 can be reduced compared to the comparative example.

The configuration of this embodiment can be modified so that the low-threshold MOS transistors including the depletion MOS transistors are used as the P-MOS 27 provided in the maximum selector 23 and the N-MOS 29 provided in the minimum selector 24, and the normal MOS transistors are used as the P-MOS 26 provided in the maximum selector 23 and the N-MOS 30 provided in the minimum selector 24.

According to this modified example, the positive side operation range of the selector 13 is the same as that of the comparative example, but the negative side operation range of the selector 13 is, for example, a range below +Vtd, which is 0V. Therefore, in the modified example, the Vmin indeterminate range is the range from +Vtd to +Vtn, that is, the range from 0V to +0.7V. As a result, in this modified example, although there is a possibility of the leakage occurring in the range of 0 V to +0.7 V because the gate voltage of the N-MOS of the switch that is turned off becomes higher than the input voltage, it is possible to restrict the leakage from occurring in the range of 0 V or less, that is, when a negative voltage is input. As described above, according to this modified example, the selector 13 always operates when the differential voltage is approximately 0 V or less, and the decrease in accuracy due to the leakage of the MOS transistors that constitutes the selector 13 can be reduced compared to the comparative example.

### <Another Application Example of SC Amplifier>

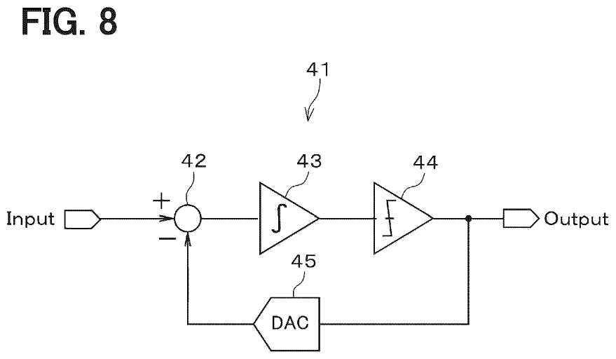

The SC amplifier 2 having the above configuration can be used as an integrator in a ΔΣ ADC. The ΔΣ ADC is an ADC that includes a ΔΣ modulator 41 as shown in FIG. 8, and obtains a high-resolution digital output by passing the output of the A2 modulator 41 through a digital filter (not shown). The 42 modulator 41 employs a type of pulse modulation method, and includes an adder 42, an integrator 43, a comparator 44, and a DAC 45.

The adder 42 outputs a signal obtained by subtracting the output signal of the DAC 45 from the input signal Input. The integrator 43 integrates the output signal of the adder 42 and can be configured by the SC amplifier 2. The comparator 44 binarizes the output signal of the integrator 43. The DAC 45 receives the output signal of the comparator 44 and outputs a signal corresponding to the input. The ΔΣ modulator 41 configured as described above integrates the input signal Input using the integrator 43, converts the output into digital form using the comparator 44, and adds or subtracts from the input signal Input using the DAC 45 according to the output, thereby extracting the output of the comparator 44 as the ΔΣ modulated output Output.

According to the above configuration, the described operation shapes the power spectral density distribution of the quantization error output by the comparator 44, in other words, performs noise shaping, thereby improving the dynamic range of the passband. With this configuration, the ADC alone can shift the level of the common mode potential, and can detect signals in a wider range than the power supply voltage or ground potential, both positive and negative. Furthermore, the above configuration can be made smaller than a configuration in which a separate level shifter is provided in the preceding stage of the ADC.

### Second Embodiment

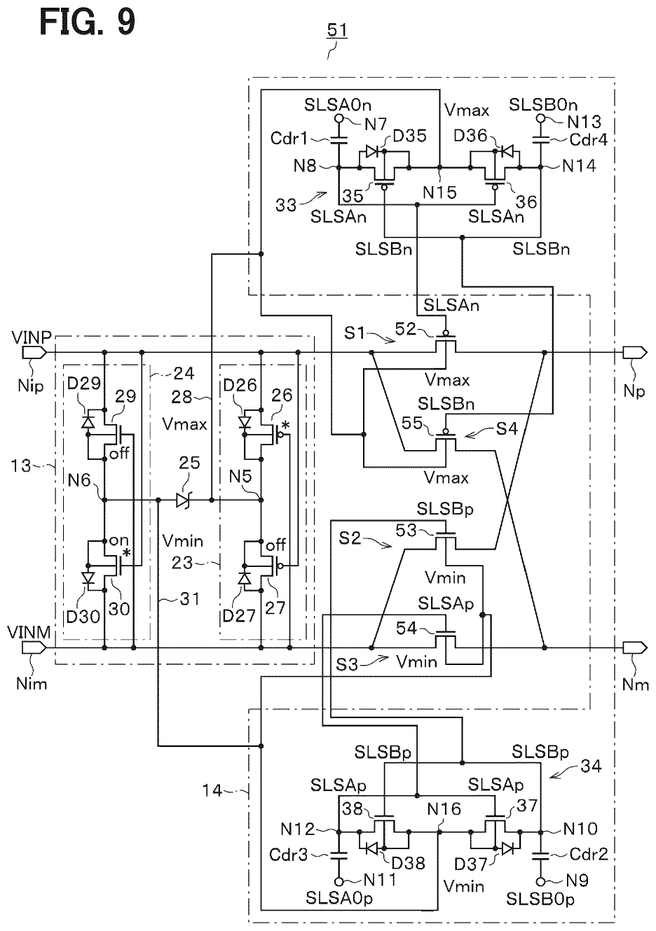

A second embodiment will be described below with reference to FIG. 9. As shown in FIG. 9, a switch circuit 51 of this embodiment differs from the switch circuit 12 of the first embodiment in the configuration of the switches S1 to S4. In this case, the high-potential side switch is made up of one P-channel MOS transistor, and the low-potential side switch is made up of one N-channel MOS transistor.

The specific configuration of the switches S1 to S4 is described as follows. The switch S1 includes one P-MOS 52. The source of the P-MOS 52 is connected to the input node Nip, and the drain is connected to the node Np. The back gate of the P-MOS 52 is connected to the signal line 28. As a result, the selection signal Vmax is given as the substrate potential of the P-MOS 52. Although not shown, a body diode exists between the body and drain of the P-MOS 52, with the drain side serving as the anode. The gate of the P-MOS 52 is connected to the capacitance couple drive unit 14, and its on/off is controlled by the capacitance couple drive unit 14.

The switch S2 is made up of one N-MOS 53. The source of the N-MOS 53 is connected to the input node Nim, and the drain is connected to the node Np. The back gate of the N-MOS 53 is connected to the signal line 31. As a result, the selection signal Vmin is given as the substrate potential of the N-MOS 53. Although not shown, a body diode with the body side serving as the anode exists between the body and drain of the N-MOS 53. The gate of the N-MOS 53 is connected to the capacitance couple drive unit 14, and its on/off is controlled by the capacitance couple drive unit 14.

The switch S3 is made up of one N-MOS 54. The source of the N-MOS 54 is connected to the input node Nim, and the drain is connected to the node Nm. The back gate of the N-MOS 54 is connected to the signal line 31. As a result, the selection signal Vmin is given as the substrate potential of the N-MOS 54. Although not shown, a body diode with the body side serving as the anode exists between the body and drain of the N-MOS 54. The gate of the N-MOS 54 is connected to the capacitance couple drive unit 14, and its on/off is controlled by the capacitance couple drive unit 14.

The switch S4 is made up of one P-MOS 55. The source of the P-MOS 55 is connected to the input node Nip, and the drain is connected to the node Nm. The back gate of the P-MOS 55 is connected to the signal line 28. As a result, the selection signal Vmax is given as the substrate potential of the P-MOS 55. Although not shown, a body diode exists between the body and drain of the P-MOS 55, with the drain side serving as the anode. The gate of the P-MOS 55 is connected to the capacitance couple drive unit 14, and its on/off is controlled by the capacitance couple drive unit 14.

Therefore, according to the present embodiment, the same effects as in the first embodiment are attained. Furthermore, according to this embodiment, since the switches S1 to S4 are each configured with one MOS transistor, the circuit can be made smaller than in the first embodiment. Here, in this embodiment in which the switches S1 to S4 are configured by one MOS transistor, there is a possibility of voltage detection errors occurring due to leakage currents caused by the body diodes of the MOS transistors.

However, in this embodiment, the selection signal Vmax output from the selector 13 is provided as the substrate potential of the P-MOS transistors 52 and 55 provided in the switches S1 and S4, and the selection signal Vmin output from the selector 13 is provided as the substrate potential of the N-MOS transistors 53 and 54 provided in the switches S2 and S3. In this way, it is possible to prevent the occurrence of leakage current due to the body diodes of the MOS transistors that constitute the switches S1 to S4.

### Third Embodiment

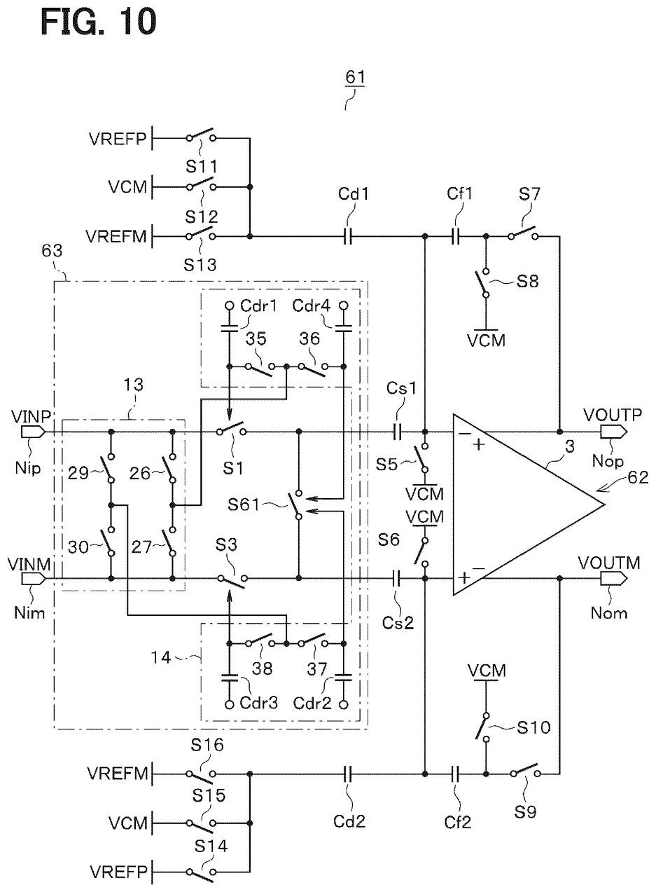

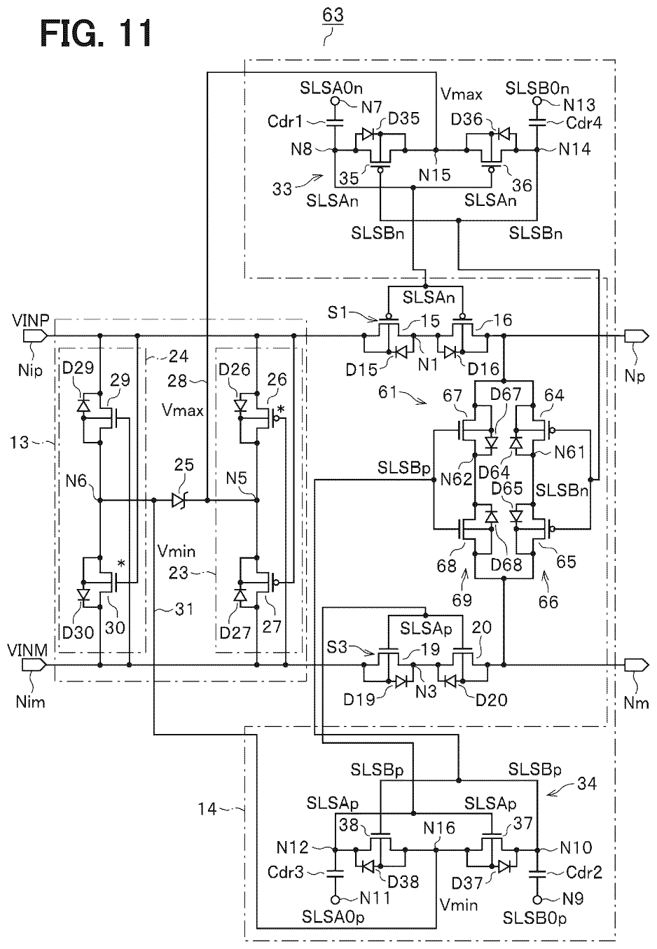

The third embodiment will be described below with reference to FIGS. 10 and 11.

### (Overall Configuration)

As shown in FIG. 10, an SC amplifier 62 provided in a voltage detection circuit 61 of this embodiment differs from the SC amplifier 2 of the first embodiment in that it includes a switch S61 instead of the switches S2 and S4. The switch S61 is connected between the second terminal of the capacitor Cs1 and the second terminal of the capacitor Cs2.

### <Specific Configuration of Switch Circuit>

In the above configuration, the multiple switches S1, S3, and S61 connected between the pair of input nodes Nip and Nim and the capacitors Cs1 and Cs2, together with the selector 13 and the capacitance couple drive unit 14, constitute a switch circuit 63, which is a CCSW circuit, as shown in FIG. 10. In FIG. 10, the configurations of the selector 13 and the capacitance couple drive unit 14 are shown in a simplified manner. The switch circuit 63 including the switches S1, S3, and S61 constitutes a part of the SC amplifier 62, and as a specific configuration thereof, for example, a configuration as shown in FIG. 11 can be adopted. The switch S61 is configured by connecting in parallel a series circuit 66 in which two P-MOS transistors 64 and 65 are connected in series, and a series circuit 69 in which two N-MOS transistors 67 and 68 are connected in series.

The source of the P-MOS 64 is connected to the node Np, and the drain thereof is connected to the node N61. The drain of the P-MOS 65 is connected to the node N61, and the source is connected to the node Nm. The node N61 is an example of an intermediate node which is an interconnection node between the two P-MOS transistors 64 and 65. The back gate of the P-MOS 64 is connected to its source. The back gate of the P-MOS 65 is connected to its source. That is, the back gates of the P-MOS transistors 64 and 65 are connected to the terminal of their source or drain that is not connected to the node N61, which is the intermediate node.

Between the body and drain of the P-MOS 64, there is a body diode D64 with the drain side serving as the anode. Between the body and drain of the P-MOS 65, there is a body diode D65 with the drain side serving as the anode. That is, in the switch S61, the body diodes D64 and D65 face each other. The gates of the P-MOS transistors 64 and 65 are connected to the capacitance couple drive unit 14, and are turned on and off by the capacitance couple drive unit 14. Specifically, the on/off of the P-MOS 64 and 65 is controlled by the drive signal SLSBn.

The source of the N-MOS 67 is connected to the node Np, and the drain is connected to the node N62. The drain of the N-MOS 68 is connected to the node N62, and the source is connected to the node Nm. The node N62 is an example of an intermediate node which is an interconnection node between the two N-MOS transistors 67 and 68. The back gate of the N-MOS 67 is connected to the source thereof. The back gate of the N-MOS 68 is connected to its source. That is, the back gates of the N-MOS transistors 67 and 68 are connected to the terminal of their source or drain that is not connected to the node N62, which is the intermediate node.

Between the body and drain of the N-MOS 67, there is a body diode D67 with the body side serving as the anode. Between the body and drain of the N-MOS 68, there is a body diode D68 with the body side serving as the anode. That is, in the switch S61, the body diodes D67 and D68 face each other. The gates of the N-MOS transistors 67 and 68 are connected to the capacitance couple drive unit 14, and are controlled by the capacitance couple drive unit 14 to be turned on or off. Specifically, the on/off of the N-MOS transistors 67 and 68 is controlled by the drive signal SLSBp.

Therefore, according to the present embodiment, the same effects as in the first embodiment are attained. The switch S61 is configured by connecting in parallel a series circuit 66 of two P-MOS transistors 64 and 65 and a series circuit 69 of two N-MOS transistors 67 and 68, and the back gates of these MOS transistors are connected to the source or drain terminal that is not connected to the intermediate node, which is the interconnection node of the two MOS transistors. In this way, in the switch S61, the body diodes of the two MOS transistors face each other, just like in the switches S1 and S3. Therefore, with the configuration of this embodiment, similar to the first embodiment, no current flows through the body diode, and no error occurs.

Further, according to the present embodiment, the following effects can be achieved. In the configuration of this embodiment, the number of switches is less by one than in the configuration of the first embodiment, and therefore, it is possible to achieve a corresponding reduction in size. Furthermore, according to the configuration of this embodiment, the operation amplifier 3 and the like are not connected to the input but are in a disconnection state during the hold operation, so that the CMRR can be increased. Note that CMRR is an abbreviation for Common Mode Rejection Ratio.

Furthermore, according to the configuration of this embodiment, the operation amplifier 3 and other components are not connected to the input during the hold operation and are therefore in a disconnection state, so that the signal at the previous stage can be switched immediately after sampling is completed. Therefore, according to this embodiment, in a configuration in which a multiplexer is provided in the preceding stage, the overall system speed can be increased.

### Other Embodiments

The present disclosure is not limited to the embodiments that have been described above and illustrated in the drawings, but can arbitrarily be modified, combined, or expanded without departing from the spirit of the present disclosure. The numerical values and the like shown in each of the above embodiments are merely examples, and the present disclosure is not limited thereto.

The selector 13 may be any device that selects one of the voltages VINP and VINM of a pair of input nodes Nip and Nim and outputs a selection signal having a potential corresponding to the selected voltage, and may be configured to include, for example, only one of the maximum selector 23 and the minimum selector 24.

The drive units 33 and 34 are only required to generate drive signals for driving the gates of the MOS transistors 15 to 22, and the like using the potential of the selection signal output from the selector 13 as a reference potential, and to supply the generated drive signals to the gates of the MOS transistors 15 to 22, and the like, and the specific configuration thereof can be changed as appropriate.

Although the present disclosure has been described according to the embodiments, it is understood that the present disclosure is not limited to the above-described embodiments or structures. The present disclosure includes various modifications or deformations within an equivalent range. In addition, while the various combinations and configurations, which are preferred, other combinations and configurations, including more, less or only a single element, are also within the spirit and scope of the present disclosure.

Further, according to the present embodiments, the following features are presented.

Feature 1: A fully differential voltage detection circuit receives a voltage from each of a pair of input nodes (Nip, Nim), detects a differential voltage between received voltages, and outputs the differential voltage from a pair of output nodes (Nop, Nom). The fully differential voltage detection circuit includes: a plurality of switches (S1 to S4) each of which includes at least one MOS transistor (15 to 22, 52 to 55) provided so as to be capable of opening and closing between the pair of input nodes and the pair of output nodes; a drive capacitor (Cdr1 to Cdr4); a drive unit (33, 34) that generates a drive signal for driving a gate of the at least one MOS transistor and supplies the drive signal to the gate of the at least one MOS transistor; a capacitance couple drive unit (14) that controls an on and off state of each of the plurality of switches by driving the gate of the at least one MOS transistor via the drive capacitor; and a selector (13) that is connected between the pair of input nodes, selects one of voltages of the pair of input nodes, and outputs a selection signal having a potential corresponding to a selected voltage. The drive unit generates the drive signal using the potential of the selection signal output from the selector as a reference potential. The selector includes two MOS transistors (26, 27, 29, 30) connected in series between the pair of input nodes. One of the two MOS transistors is a normal MOS transistor having a normal threshold voltage. The other of the two MOS transistors is a low-threshold MOS transistor having a threshold lower than the normal threshold.

Feature 2: In the voltage detection circuit according to feature 1, the selector includes: a maximum selector (23) that selects a higher voltage of the voltages of the pair of input nodes and outputs the selection signal having the potential corresponding to a selected higher voltage; and a minimum selector (24) that selects a lower voltage of the voltages of the pair of input nodes and outputs the selection signal having the potential corresponding to a selected lower voltage. The two MOS transistors included in the maximum selector are P-channel MOS transistors (26, 27). The two MOS transistors included in the minimum selector are N-channel MOS transistors (29, 30). Each of the maximum selector and the minimum selector is configured to output a signal at an intermediate node (N5, N6) between the two MOS transistors as the selection signal.

Feature 3: In the voltage detection circuit according to feature 1 or 2, the low-threshold MOS transistor is a depletion MOS transistor.

Feature 4: In the voltage detection circuit according to any one of features 1 to 3, a high potential side of the pair of input nodes is defined as a high potential side input node; a low potential side of the pair of input nodes is defined as a low potential side input node; a switch connected to the high potential side input node among the plurality of switches is defined as a high potential side switch; and a switch connected to the low potential side input node among the plurality of switches is defined as a low potential side switch. The high potential side switch includes one P-channel MOS transistor (52, 55). The low potential side switch includes one N-channel MOS transistor (53, 54).

Feature 5: In the voltage detection circuit according to any one of features 1 to 3, a high potential side of the pair of input nodes is defined as a high potential side input node; a low potential side of the pair of input nodes is defined as a low potential side input node; a switch connected to the high potential side input node among the plurality of switches is defined as a high potential side switch; and a switch connected to the low potential side input node among the plurality of switches is defined as a low potential side switch. The high potential side switch includes two P-channel MOS transistors (15, 16, 21, 22) connected in series. The low potential side switch includes two N-channel MOS transistors (17, 18, 19, 20) connected in series.

Feature 6: In the voltage detection circuit according to any one of features 1 to 5, the selection signal output from the selector is given as a substrate potential of the MOS transistor included in the plurality of switches.

Feature 7: The voltage detection circuit according to any one of features 1 to 6, further includes: a switched capacitor amplifier (2). The plurality of switches constitute a part of the switched capacitor amplifier.

Feature 8: In the voltage detection circuit according to any one of features 1 to 7, the pair of input nodes is connectable to a terminal of each battery cell that is included in a battery assembly (4). The plurality of switches constitute a part of a level shift circuit that reduces a relatively high common-mode voltage superimposed on each of the battery cells (4 a, 4 b) to a relatively low common-mode voltage.

Feature 9: In the voltage detection circuit according to any one of features 1 to 8, the drive capacitor is a comb-tooth capacitor.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A fully differential voltage detection circuit that receives a voltage from each of a pair of input nodes, detects a differential voltage between received voltages, and outputs the differential voltage from a pair of output nodes, the fully differential voltage detection circuit comprising:
a plurality of switches each of which includes at least one MOS transistor provided so as to be capable of opening and closing between the pair of input nodes and the pair of output nodes;
a capacitance couple drive unit that includes: a drive capacitor; and a drive unit that generates a drive signal for driving a gate of the at least one MOS transistor and supplies the drive signal to the gate of the at least one MOS transistor, and controls an on and off state of each of the plurality of switches by driving the gate of the at least one MOS transistor via the drive capacitor; and
a selector that is connected between the pair of input nodes, selects one of voltages of the pair of input nodes, and outputs a selection signal having a potential corresponding to a selected voltage, wherein:
the drive unit generates the drive signal using the potential of the selection signal output from the selector as a reference potential;
the selector includes two MOS transistors connected in series between the pair of input nodes;
one of the two MOS transistors is a normal MOS transistor having a normal threshold voltage; and
an other of the two MOS transistors is a low-threshold MOS transistor having a threshold lower than the normal threshold.

2. The fully differential voltage detection circuit according to claim 1, wherein:
the selector includes:
a maximum selector that selects a higher voltage of the voltages of the pair of input nodes and outputs the selection signal having the potential corresponding to a selected higher voltage; and
a minimum selector that selects a lower voltage of the voltages of the pair of input nodes and outputs the selection signal having the potential corresponding to a selected lower voltage;
the two MOS transistors included in the maximum selector are P-channel MOS transistors;
the two MOS transistors included in the minimum selector are N-channel MOS transistors; and
each of the maximum selector and the minimum selector is configured to output a signal at an intermediate node between the two MOS transistors as the selection signal.

3. The fully differential voltage detection circuit according to claim 1, wherein:
the low-threshold MOS transistor is a depletion MOS transistor.

4. The fully differential voltage detection circuit according to claim 1, wherein:
a high potential side of the pair of input nodes is defined as a high potential side input node;
a low potential side of the pair of input nodes is defined as a low potential side input node;
a switch connected to the high potential side input node among the plurality of switches is defined as a high potential side switch;
a switch connected to the low potential side input node among the plurality of switches is defined as a low potential side switch;
the high potential side switch includes one P-channel MOS transistor; and
the low potential side switch includes one N-channel MOS transistor.

5. The fully differential voltage detection circuit according to claim 1, wherein:
a high potential side of the pair of input nodes is defined as a high potential side input node;
a low potential side of the pair of input nodes is defined as a low potential side input node;
a switch connected to the high potential side input node among the plurality of switches is defined as a high potential side switch;
a switch connected to the low potential side input node among the plurality of switches is defined as a low potential side switch;
the high potential side switch includes two P-channel MOS transistors connected in series; and
the low potential side switch includes two N-channel MOS transistors connected in series.

6. The fully differential voltage detection circuit according to claim 1, wherein:
the selection signal output from the selector is given as a substrate potential of the at least one MOS transistor included in each of the plurality of switches.

7. The fully differential voltage detection circuit according to claim 5, further comprising:
a switched capacitor amplifier, wherein:
the plurality of switches constitute a part of the switched capacitor amplifier.

8. The fully differential voltage detection circuit according to claim 7, wherein:
the pair of input nodes is connectable to a terminal of each of a plurality of battery cells that are included in a battery assembly; and
the plurality of switches constitute a part of a level shift circuit that reduces a relatively high common-mode voltage superimposed on each of the plurality of battery cells to a relatively low common-mode voltage.

9. The fully differential voltage detection circuit according to claim 8, wherein:
the drive capacitor is a comb-tooth capacitor.
